(19) United States
(12) Patent Application Publication
(10) Pub. No.: US 2002/0052673 A1
(43) Pub. Date: May 2, 2002

(54) Digital online active test plant protection system in a nuclear power plant and method thereof

(75) Inventors: Poong Hyun Seong, Taejun (KR); Han Seong Son, Taejun (KR); Seo Ryong Koo, Taejun (KR)

Correspondence Address: AKIN, GUMP, STRAUSS, HAUER & FELD, L.L.P., ONE COMMERCE SQUARE, 2005 MARKET STREET, SUITE 2200, PHILADELPHIA, PA, 19103, US

(73) Assignee: Korea Advanced Institute of Science and Technology

(21) Appl. No.: 09/777,108

(22) Filed: Feb. 5, 2001

(30) Foreign Application Priority Data
Nov. 1, 2000 (KR) 2000-64672

(51) Int. Cl. G05B 11/01; H04L 1/22; H04B 1/74; H02H 3/05; H05K 10/00; H03K 19/003; G05D 3/12; G05D 5/00; G05D 9/00; G05D 11/00; G05D 17/00

(52) U.S. Cl. 700/292; 700/21; 700/11; 714/1

(57) ABSTRACT

There is disclosed an improved digital software-based reactor protection system and an engineered safety feature actuation system. A digital online active test plant protection system in a nuclear power plant according to the present invention comprises a test generating computer (TGC) for generating a test input being a command to initiate a test and a test signal position bit indicating that the test input is currently generated at what position of the process parameters; a trip algorithm computer (TAC) for receiving plant operating parameters via a plurality of measuring channels physically and electrically isolated and then comparing the measured operating parameters and a predetermined limit values to determine a trip state, if there is a test input by the TGC; a voting algorithm computer (VAC) for receiving trip signals from each of the plant operating parameters determined by the TAC, determining whether a reactor has to be stopped or not and then outputting a signal to stop the reactor; and a pattern recognition computer (PRC) for expecting a signal pattern from the state of the reactor, comparing the signal pattern with the reactor trip signal generated by the VAC, and then if the signal pattern and the reactor trip signal are not consistent, determining to stop the reactor.

### TECHNICAL FIELD

The invention relates generally to a protection system for nuclear power plant and method thereof. More particularly, the present invention relates to an improved digital software-based reactor protection system and an engineering safety equipment operating system.

### BACKGROUND OF THE INVENTION

A nuclear power plant is a system to which safety is very important in view of its characteristic. One of important roles that must be played for the safety of the nuclear power plant is a reactor protection system. A Instrument and Control (I&C) system including the reactor protection system is a system that serves as brains of humans in a nuclear power plant, which significantly affects its operation as well as safety of the entire nuclear power plant. Therefore, improvement in the performance of the I&C system such as the nuclear protection system and safety of reliability of a high level will provide significant effects to economic benefits and improved safety in the nuclear power plant.

Most of a reactor protection system in a pressurized light-water nuclear power plant, now widely used in the domestic, is based on an analog circuit, which is composed of a process measuring system consisted of a lot of analog circuit substrates and a solid state protection system (SSPS) made of hardware for performing LCL.

The reactor protection system has several problems, which will be explained as follows.

First, as it is based on an analog circuit, there is a problem in a circuit itself such as drift and worn-out of components.

Second, it requires a periodic check for maintenance. As this check nearly entirely depends on manpower, however, there is a problem that a significant amount of cost and time is wasted.

Third, there is a problem that the reactor is unnecessarily stopped during the check.

Meanwhile, now only the reactor protection system itself is a system consisted of high value-added nuclear power plant safety-class equipments but also most of a rector for receiving signals and other constituent elements are a nuclear power plant safety-class equipments. As most of the nuclear power plant safety-class equipments require technology of a high level, a lot of cost for development and purchase are required. In particular, as the I&C system depending on a foreign technology additionally bears an engineering cost of 3 to 4 times to the cost for manufacturing the equipment, there is a great economic burden. As a concrete example, the plant control system (PCS) included in Gori 2th SSPS costs about 18 millions dollars. If this nuclear power plant I&C system is localized, the engineering cost as well as the manufacturing cost could be significantly reduced. Also, considering that the level of technology in which the nuclear power plant I&C system requires is significantly high, it could be expected that the level of the I&C system related industries could be increased accordingly. In this view, it is very meaningful to localize the reactor protection system that is the core in the nuclear power plant I&C system.

In order to overcome these problems, it is necessary to develop a software based digital nuclear power plant protection system.

Meanwhile, examining a digital plant protection system (DPPS), which has been developed in order to solve the above-mentioned problems, there has been proposed a passive test method in which an alert is issued by an interface & test processor if any problem occurred while continuously monitoring the bi-stable process and a LCL processor, and an active test method by which a specific channel is bypassed and a test signal is applied to compare an output signal and a feedback signal.

In the passive test method being an online test, the state of the system is continuously monitored. However, the active test method bypasses and then periodically performs a test, which could not continuously monitor the state of the system.

As a result, as the system test in the conventional digital plant protection system monitors the state of respective channels and components, there is an advantage that relatively detailed information on malfunction of specific components may be obtained. However, as it accordingly requires the software of higher complexity and the system test itself is passive, though the system stability could be continuously monitored in a normal state of operation, there is a problem that the stability in the stop state of the reactor could not be secured.

### SUMMARY OF THE INVENTION

The present invention is contrived to solve the above problems and an object of the present invention is to provide an improved digital software-based reactor protection system and an engineering safety equipment operating system, which can be applied to present nuclear power plants.

In order to accomplish the above objects, a digital online active test—plant protection system (DOAT-PPS) in a nuclear power plant according to the present invention is characterized in that it comprises a test generating computer (TGC) for generating a test input being a command to initiate a test and a test signal position bit indicating that the test input is currently generated at what position of the process parameters; a trip algorithm computer (TAC) for receiving plant operating parameters via a plurality of measuring channels physically and electrically isolated and then comparing the measured operating parameters and a predetermined limit values to determine a trip state, if there is a test input by the TGC; a voting algorithm computer (VAC) for receiving trip signals from each of the plant operating parameters determined by the TAC, determining whether a reactor has to be stopped or not and then outputting a signal to stop the reactor; and a pattern recognition computer (PRC) for expecting a signal pattern from the state of the reactor, comparing the signal pattern with the reactor trip signal generated by the VAC, and then if the signal pattern and the reactor trip signal are not consistent, determining to stop the reactor.

Further, a digital online active test plant protection method in a nuclear power plant comprises a first step of generating a test input being a command to initiate a test and a test signal position bit indicating that the test input is currently generated at what position of the process parameters; a second step of receiving plant operating parameters via a plurality of measuring channels physically and electrically isolated and then comparing the measured operating parameters and a predetermined limit values to determine a trip state, if there is a test input in the first step; a third step of receiving trip signals from each of the plant operating parameters determined by said second step, determining whether a reactor has to be stopped or not and then outputting a signal to stop the reactor; and a fourth step of expecting a signal pattern from the state of the reactor, comparing the signal pattern with the reactor trip signal generated by the third step, and then if the signal pattern and the reactor trip signal are not consistent, determining to stop the reactor.

Further, in a recording medium readable by a computer and on which a program is recorded, the program executes a first step of generating a test input being a command to initiate a test and a test signal position bit indicating that the test input is currently generated at what position of the process parameters; a second step of receiving plant operating parameters via a plurality of measuring channels physically and electrically isolated and then comparing the measured operating parameters and a predetermined limit values to determine a trip state, if there is a test input in the first step; a third step of receiving trip signals from each of the plant operating parameters determined by the second step, determining whether a reactor has to be stopped or not and then outputting a signal to stop the reactor; and a fourth step of expecting a signal pattern from the state of the reactor, comparing the signal pattern with the reactor trip signal generated by the third step, and then if the signal pattern and the reactor trip signal are not consistent, determining to stop the reactor.

### BRIEF DESCRIPTION OF THE DRAWINGS

The aforementioned aspects and other features of the present invention will be explained in the following description, taken in conjunction with the accompanying drawings, wherein:

FIG. 1 is a schematic view of a digital online active test—plant protection system (DOAT-PPS) according to one embodiment of the present invention; and

FIG. 2 is a diagram illustrating the difference between a conventional digital plant protection system (DPPS), a dynamic safety system (DDS) and the DOAT-PPS according to one embodiment of the present invention.

### DETAILED DESCRIPTION OF THE INVENTION

A digital online active test—plant protection system (hereinafter called “DOAT-PPS”) according to one embodiment of the present invention will be described in detail with reference to accompanying drawings.

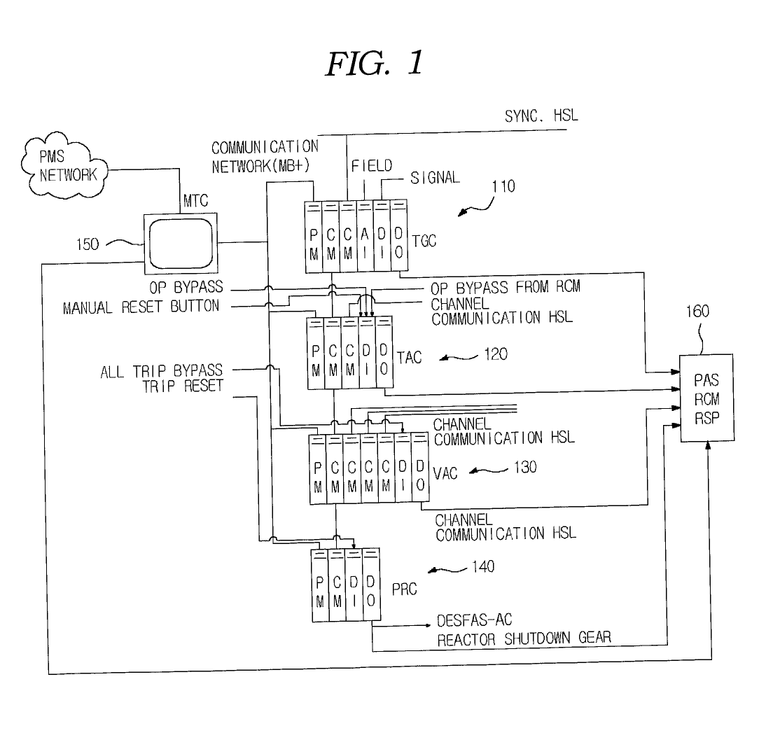

FIG. 1 is a schematic view of the DOAT-PPS according to one embodiment of the present invention. First, the major components of the DOAT-PPS includes a test generating computer (TGC) 110 for generating test, a trip algorithm computer (TAC) 120 for receiving a safety parameter signal to compare it with a trip set value and to generate a trip signal, a voting algorithm computer (VAC) 130 for receiving trip signals from other channels to perform a logic, a pattern recognition computer (PRC) 140 for generating a rector trip signal, a manual test computer (MTC) 150 for providing an input and output function by which an operator can monitor and control input/output signals from the TGC 110, the TAC 120, the VAC 130 and the PRC 140, and a remote control module (RCM) 160 installed at a main control panel, for displaying the operating state of the system and for performing various functions necessary to monitor the test and maintain the system.

The DOAT-PPS according to one embodiment of the present invention is composed of independent four measuring channels (A, B, C and D).

The reactor trip signal is generated when more than two measuring channels among the four measuring channels, that are physically and electrically isolated, surpass a predetermined trip set value. At this time, the trip set value is a value predetermined for the reactor operating parameters. If the trip set value is surpassed, it means the state of the reactor is unstable, which will be in detail explained later.

In other words, the function of the reactor protection system is to minimize the possibility that radioactivity can be leaked from surrounding environments by stopping the reactor, when the nuclear power plant is entered into an abnormal state out of a normal operating state. The reactor protection system receives signals from the reactor and other components to generate a trip signal using trip logic when they get out of normal operation conditions.

The signals inputted into the four independent channels are inputted to the TAC 120 via the TGC 110. Here, the TGC 110 is an integral portion of a digital online active test according to the present invention, which generates a test input and a test signal position bit.

At this time, the test input is a command to start the test. Also, the test signal position bit assists the function of the test input generated at the TGC 110 and also functions to inform that the test input is generated at what position of the process parameters. In other words, the DOAT-PPS automatically continuously performs an active test and generates a test input to determine whether respective components are stable or not by replacing an actual input. Therefore, knowing where the test input is located is a very important factor and the test signal position bit functions to inform this position to entire components. Also, a diagnosis for each of the TAC 120, the VAC 130 and the PRC 140 can be made in real time using the test signal position bit.

The TAC 120 generates a self-diagnosis test signal and uses the test signal to transmit the trip signal to the VAC 130. That is, the reactor trip signal determined by the TAC in one channel enters the VACs 130 in the four channels as an input signal, and the VAC 130 determines whether the reactor has stopped or not by means of an adequate select logic (generally 2/4 logic).

Meanwhile, the PRC 140 expects a signal pattern from a current state of the reactor and then compares it with the reactor trip signal generated by the VAC 130. As a result of the comparison, if they do not match, the PRC 140 determines that the reactor stop should be stopped and transmits it to respective initiation logics.

Also, the MTC 150 provides an input and output function by which an operator can monitor and control input/output signals from the TGC 110, the TAC 120, the VAC 130 and the PRC 140.

In addition, the RCM 160, which is installed at a main control panel, displays the operating system of the system and performs various functions necessary for monitoring and maintenance of the system.

Each of the components of will be below explained in more detail.

First, the TGC 110 is a core portion of a digital online active test according to the present invention and generates a test input and a test signal position bit, which initiates a test automatically.

If the test is automatically initiated, the TAC 120 receives plant operation parameters as an input signal from an environment neutron flux monitoring system (ENFMS), a remote stop panel and a core protection calculation system (CPCS) via an analog input module or a digital input module. Also, the TAC 120 contains a stop algorithm and performs the two following functions.

First, it determines whether the reactor has stopped or not using the stop algorithm.

Second, it controls the TGC 110. The TGC 110 generates a test input making respective operating parameters into reactor stop states depending on the stop algorithm. The test input is actually inserted between plant signals. The initiation software of the TAC 120 compares the measured operating parameter values and the predetermined limit value to determine a trip state using the trip algorithm. The trip signal is transmitted to the VAC 130 via a programmable logic control (PLC) digital output module. That is, the TAC 120 generates a test signal for self-diagnosis by means of the logic and transmits the trip signal to the VAC 130 using the test signal.

In the embodiment of the present invention, if the TAC 120 is implemented using PLC, it is consisted of a central process module, a power supply module, an analog input module, a digital input module and a digital output module.

Meanwhile, the plant stop operating parameters, which are applied to the input terminal of the TAC 120, are as follows.

First, it is a variable over power trip. The change ratio of the neutron flux level is increased over a program set value or the neutron flux reaches a predetermined maximum value, the reactor is stopped. There is a difference of about 15% between the output and the trip set value. If the output of the reactor is increased, the trip set value is also decreased to maintain the range of 13.6%. If the output of the reactor is reduced, the trip set value is maintained at 13.6%. As the maximum increased ratio of the trip set value is 14.6%/min, however, if the output of the reactor is increased over the maximum, a trip of the reactor is occurred. The purpose of this trip is to assist the engineering safety equipment operating system for mitigating the result of an accident when a control rod is extracted.

Second, it is a high logarithmic power level trip. The high logarithmic power level trip is initiated in order to stop the reactor when a predetermined neutron flux output reaches a predetermined maximum value. The purpose of this trip is to secure safety of a cloth and a reactor coolant pressure boundary when accidents such as dilution of boric acid or extraction of an uncontrollable control rod are occurred.

Third, it is a high local power density trip. When a core maximum output density is locally over a specific value, the reactor is stopped. This is caused by generation of a trip signal in the core protection calculator. The input signal used in the trip signal is an output, the location of the control rod, the temperature, pressure and flow rate of the reactor coolant, etc. The purpose of this trip is that the local output density does not surpass the design limit value upon medium frequency and rare frequency accidents. The local output density is calculated in the core protection calculator using the output of a neutron flux and the distribution of a radial-directional output, the output of a radial-direction tip by the measurement of the location of respective rods, and the temperature of the reactor coolant and the output between the temperatures by measurement of the flow rate. The local power density reactor stop parameters calculated by the core protection calculator (CPC) are ones that considered an error and a dynamic compensation. This ensures that the tip value of the core local output density does not surpass the limit value of the local output density safety limit value after the reactor is stopped when the core local output tip value is actually sufficiently lower than the nuclear fuel design limit value. The dynamic compensation considers the transfer delay of the core fuel center temperature (related to variations of the output density), delay time of the detector and time delay effect of the protection system. A method of calculating an error of the core protection calculator related to the tip local power density is same to the method used in Departure From Nucleate Boiling Ratio (DNBR) calculation, wherein the DNBR is a physical amount indicating that a cooling water for cooling a nuclear fuel rod within the reactor is boiled to generate bubbles.

Fourth, it is a low Departure From Nucleate Boiling Ratio trip. If the NBR reaches a predetermined minimum value, the reactor will be stopped. That is, it assists the engineering safety equipment operating system for mitigating the result when the reactor coolant pump is out of order or the vapor generator is leaked. The NBR may be calculated in the core protection calculator using the neutron flux output and the axial-directional output distribution by the neutron detector in the reactor, the radial-direction tip output by measurement of the locations of each of the control rods, the output between the temperatures by measurement of the temperature and the flow rate of the reactor coolant, the pressure of the coolant system by measurement of the pressure of the pressurizer, the flow rate of the coolant by the speed of the reactor coolant pump and the core inlet temperature by measurement of the reactor coolant low temperature tube. In this case, considering the delay of the detector and the processing time and inaccuracy, a trip is generated before the NBR surpasses the safety limit value. Also, the calculation method uses a DNBR calculation method, which ensures that the reactor can be stopped in a state that the calculated DNBR is sufficiently higher than 1.30 so that it does not override the DNBR safety limit value even though the core DNBR value is reduced. The dynamic compensation indicates the transfer delay of the coolant, the thermal delay of the core (related to the core output variations), the time delay of the detector, the time delay of the protection system, etc. The error of the core protection calculator related to the DNBR calculation includes an input measurement error of the core protection calculator, a calculation equation modeling error and a computer process error. The DNBR calculation equation used in the core protection calculator is effective within the predetermined limit value. Therefore, if the core protection calculator is operated out of the limit value, it generates a DNBR/LPD trip signal.

Fifth, it is a high pressurizer pressure trip. This trip is to secure a safety of the reactor coolant pressure boundary when the medium frequency and the rare frequency, which could be over-pressured, are occurred. If the pressure of the pressurizer is over the set value, the reactor trip is occurred and extraction of the control rod is prohibited.

Sixth, it is a low pressurizer pressure trip. This trip assists the NBR trip, prevents accessing the safety limit value ands assists the engineering safety equipment system when an accident such as loss of the coolant is occurred. When the plant is stopped or cooled, it allows the operator to manually decrease the set value. If the pressure is increased, the set value is increased with a given difference.

Seventh, it is a low steam generator level trip. This trip prevents that the reactor is pressurized due to absence of a thermal removal source such as loss of a water supply. That is, when the water level of the steam generator is reduced, a protection action is taken to ensure a time sufficient to operate the assistant water supply pump for removing remaining heat.

Eighth, it is a high steam generator level trip. This trip prevents moisture from a steam generator from entering the turbine, thus preventing damage of the equipment. That is, if the level of each of the steam generators surpasses the set value, a trip of the reactor is occurred.

Ninth, it is a low steam generator pressure trip. This trip assists the engineering safety equipment system in order to prevent the reactor coolant from cooling when a steam tube is disrupted.

Tenth, it is a low reactor coolant flow trip. This trip senses the pressure difference between the front and the rear stairs in the first side of the steam generator. Thus, if this pressure difference falls by a significant ratio or under a predetermined minimum value, a trip of the reactor is occurred.

Eleventh, it is a high containment pressure trip. This trip sets the pressure of the container not t surpass the design pressure when accidents such as loss of a design standard coolant or damage of a main steam tube within the containment are occurred. That is, if the pressure within the containment reaches the set value, a trip signal of the reactor is occurred.

Twelfth, it is a manual reactor trip. This trip provides a means for tripping the reactor in the main control room. Also, it is made possible in the reactor trip switching gear.

The VAC 130 receives trip signals of respective safety parameters determined by the TAC 120 and a trip channel bypass signal related to it. At this time, it is operated depending on a confirm algorithm by which only one channel can be bypassed at a time. Here, the trip channel bypass means that when one of the four channels could not be operated by an accident, it functions to remove that channel.

In the present embodiment, if signals from more than two channels of the four measuring channels indicate trip states, trip signals are outputted to corresponding safety parameters. If the trip channel bypass exists, more than two of the three trip signals that are not bypassed indicate trip states, a trip signal is outputted. Also, it receives position information of the test trip signal for self-diagnosis generated by the TAC 120 and then outputs it to the PRC 140.

The RPC 140 receives the trip signal of each of the safety parameters determined by the VAC 130 and the position information of the test trip signal for self-diagnosis. As the trip generated in the safety parameters corresponding to the test trip position means that the system is normal, it does not generate a reactor trip signal. When the trip of the safety parameters not corresponding to the test trip position and the safety parameters of the test trip location are normally received, however, a reactor trip signal is generated.

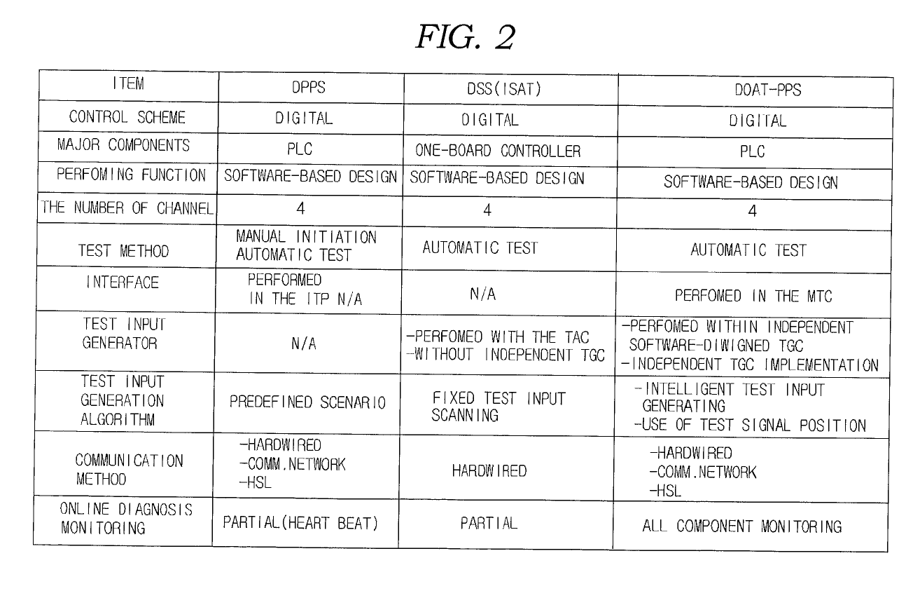

Referring now to FIG. 2, the difference between the conventional digital plant protection system (DPPS), a dynamic safety system (DSS) and the DOAT-PPS according to one embodiment of the present invention will be in detail explained below.

Though all of the three systems are similar since they are based on a software-based digital system, the two systems are different from the DOAT-PPS in several detailed points.

First, examining a control scheme, all of the systems are a software based digital system. Examining major apparatuses, the DSS adopts a board controller scheme but the DPPS and the DOAT-PPS employ a PLL scheme.

Also, all of the three systems perform functions based on the software and have the number of four measuring channels. In view of a test method, the DPPS must be directly initiated by an operator but the DSS and the DOAT-PPS are automatically initiated.

Further, examining a system interface scheme, the DPPS uses an interface & test processor (ITP) scheme but the DSS does not have a specified scheme and the DOAT-PPS is performed in the MTC.

Also, in the test input generation algorithm, the DPPS adopts a predefined scenario algorithm, the DSS adopts a fixed test input algorithm and the DOAT-PPS adopts an intelligent test input generating algorithm and an input signal position bit algorithm.

Also, examining the online diagnostic monitoring section, the DPPS and the DSS adopt a partial diagnostic monitoring scheme but the DOAT-PPS adopts a diagnosis monitor scheme for all the components.

The present invention has been described with reference to a particular embodiment in connection with a particular application. Those having ordinary skill in the art and access to the teachings of the present invention will recognize additional modifications and applications within the scope thereof.

It is therefore intended by the appended claims to cover any and all such applications, modifications, and embodiments within the scope of the present invention.

As mentioned above, the present invention has outstanding advantages that it can design an intelligent test system capable of monitoring the state of all the components as well as all types of errors and it can improve the use and the maintenance.

What is claimed is:

1. A digital online active test—plant protection system (DOAT-PPS) in a nuclear power plant, comprising:
a test generating computer (TGC) for generating a test input being a command to initiate a test and a test signal position bit indicating that said test input is currently generated at what position of the process parameters;
a trip algorithm computer (TAC) for receiving plant operating parameters via a plurality of measuring channels physically and electrically isolated and then comparing the measured operating parameters and a predetermined limit values to determine a trip state, if there is a test input by said TGC;
a voting algorithm computer (VAC) for receiving trip signals from each of the plant operating parameters determined by said TAC, determining whether a reactor has to be stopped or not and then outputting a signal to stop the reactor; and
a pattern recognition computer (PRC) for expecting a signal pattern from the state of the reactor, comparing the signal pattern with the reactor trip signal generated by said VAC, and then if the signal pattern and the reactor trip signal are not consistent, determining to stop the reactor.

2. The digital online active test—plant protection system (DOAT-PPS) in a nuclear power plant according to claim 1, wherein the plant operating parameters received from said TAC include a variable over power trip for stopping the reactor if the change ratio of the neutron flux is increased over a program set value or the neutron flux reaches a predetermined maximum value; a high logarithmic power level trip for securing the safety of a cloth and a reactor coolant pressure boundary when accidents such as dilution of boric acid or extraction of an uncontrollable control rod are occurred; a high local power density trip for stopping the reactor when a core maximum output density is locally over a specific value; a low Departure From Nucleate Boiling Ratio (DNBR) trip for stopping the reactor when the DNBR reaches a predetermined minimum value; a high pressurizer pressure trip for ensuring the safety of the reactor coolant pressure boundary when a medium frequency and a rare frequency, which could be over-pressured, are occurred; a low pressurizer pressure trip for assisting the DNBR trip, preventing accessing the safety limit value ands assisting an engineering safety equipment system when an accident of loss of the coolant is occurred; a low steam generator level trip for preventing that the reactor is pressurized due to absence of a thermal removal source such as loss of a water supply; a high steam generator level trip for not allowing moisture from a vapor generator to enter a turbine to prevent damage of the components; a low steam generator pressure trip for assisting an engineering safety equipment system in order to prevent the reactor coolant from cooling when a steam tube is disrupted; a low reactor coolant flow trip for sensing the pressure difference between the front and rear stairs in the primary side of the steam generator and for generating a reactor trip if the pressure difference falls by a significant ratio or under a predetermined minimum value; a high containment pressure trip for generating a reactor trip signal if the containment pressure reaches a set value; and a manual reactor trip by which the reactor can be tripped in a main control room.

3. The digital online active test—plant protection system (DOAT-PPS) in a nuclear power plant according to claim 1, further include a manual test computer (MTC) for providing an input and output function by which an operator can monitor and control input/output signals from said TGC, said TAC, said VAC and said PRC.

4. The digital online active test—plant protection system (DOAT-PPS) in a nuclear power plant according to claim 1, further includes a remote control module (RCM) installed at a main control room, for displaying the operating state of the system and for performing various functions necessary to monitor the test and maintain the system.

5. A digital online active test plant protection method in a nuclear power plant, comprising:
a first step of generating a test input being a command to initiate a test and a test signal position bit indicating that said test input is currently generated at what position of the process parameters;
a second step of receiving plant operating parameters via a plurality of measuring channels physically and electrically isolated and then comparing the measured operating parameters and a predetermined limit values to determine a trip state, if there is a test input in said first step;
a third step of receiving trip signals from each of the plant operating parameters determined by said second step, determining whether a reactor has to be stopped or not and then outputting a signal to stop the reactor; and
a fourth step of expecting a signal pattern from the state of the reactor, comparing the signal pattern with the reactor trip signal generated by said third step, and then if the signal pattern and the reactor trip signal are not consistent, determining to stop the reactor.

6. The digital online active test—plant protection method in a nuclear power plant according to claim 3, wherein the plant operating parameters include a variable over power trip for stopping the reactor if the change ratio of the neutron flux is increased over a program set value or the neutron flux reaches a predetermined maximum value; a high logarithmic power level trip for securing the safety of a cloth and a reactor coolant pressure boundary when accidents such as dilution of boric acid or extraction of an uncontrollable control rod are occurred; a high local power density trip for stopping the reactor when a core maximum output density is locally over specific values; a low Departure From Nucleate Boiling Ratio (DNBR) trip for stopping the reactor when the DNBR reaches a predetermined minimum value; a high pressurizer pressure trip for ensuring the safety of the reactor coolant pressure boundary when a medium frequency and a rare frequency, which could be over-pressured, are occurred; a low pressurizer pressure trip for assisting the DNBR trip, preventing accessing the safety limit value ands assisting an engineering safety equipment system when an accident of loss of the coolant is occurred; a low steam generator level trip for preventing that the reactor is pressurized due to absence of a thermal removal source such as loss of a water supply; a high steam generator level trip for not allowing moisture from a vapor generator to enter a turbine to prevent damage of the components; a low steam generator pressure trip for assisting an engineering safety equipment system in order to prevent the reactor coolant from cooling when a steam tube is disrupted; a low reactor coolant flow trip for sensing the pressure difference between the front and rear stairs in the primary side of the steam generator and for generating a reactor trip if the pressure difference falls by a significant ratio or under a predetermined minimum value; a high containment pressure trip for generating a reactor trip signal if the containment pressure reaches a set value; and a manual reactor trip by which the reactor can be tripped in a main control room.

7. A recording medium readable by a computer and on which a program is recorded, said program executing:
a first step of generating a test input being a command to initiate a test and a test signal position bit indicating that said test input is currently generated at what position of the process parameters;
a second step of receiving plant operating parameters via a plurality of measuring channels physically and electrically isolated and then comparing the measured operating parameters and a predetermined limit values to determine a trip state, if there is a test input in said first step;
a third step of receiving trip signals from each of the plant operating parameters determined by said second step, determining whether a reactor has to be stopped or not and then outputting a signal to stop the reactor; and
a fourth step of expecting a signal pattern from the state of the reactor, comparing the signal pattern with the reactor trip signal generated by said third step, and then if the signal pattern and the reactor trip signal are not consistent, determining to stop the reactor.
